(19) United States
(12) Patent Application Publication
(10) Pub. No.: US 2010/0109668 A1
(43) Pub. Date: May 6, 2010

(54) Medical Examination or Treatment Facility, in Particular a Magnetic Resonance Facility

(76) Inventor: Bernd Maciejewski, Markt Erlbach (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/608,253

(22) Filed: Oct. 29, 2009

(30) Foreign Application Priority Data
Oct. 30, 2008 (DE) 10 2008 053 845.0

(51) Int. Cl. G01R 33/44

(52) U.S. Cl. 324/318

(57) ABSTRACT

A medical examination or treatment facility is proposed. The medical examination or treatment facility, which is a magnetic resonance facility in particular, comprises a main unit and a support structure that can be fastened to the main unit, the support structure being a profile frame structure. Because of their particular form profile frames allow a wide range of components to be fastened without major outlay. They are simple, stable and flexible to use and allow a significant cost reduction compared with conventional steel structures. The profiles in the profile frames allow changes to be made easily to the arrangement of fastened parts at any time by moving fastening units in the profile frames.

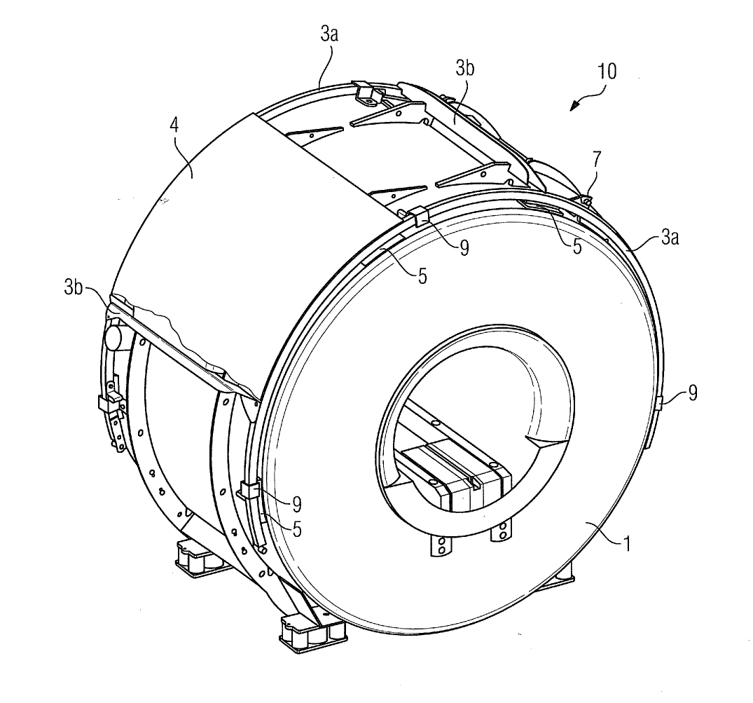

### CROSS REFERENCE TO RELATED APPLICATIONS

This application claims priority of German application No. 10 2008 053 845.0 filed Oct. 30, 2008, which is incorporated by reference herein in its entirety.

### FIELD OF THE INVENTION

The invention relates to a medical examination or treatment facility, in particular a magnetic resonance facility.

### BACKGROUND OF THE INVENTION

Known examination or treatment facilities, in particular in the form of a magnetic resonance facility, but also for example in the form of a computed tomography unit or radiation facility, generally provide a number of separate external casing parts, to encase the facility externally. The casing here is fastened to a central main unit of the examination or treatment facility. The main unit here is a magnet unit of a magnetic resonance facility for example or a gantry of a computed tomography unit or radiation facility. To fasten the casing parts, stirrups or frames, made for example from simple steel structures, are frequently fastened to the main unit so that they can serve as supports for the casing. Less frequently the casing is fastened to the main unit directly, for example by means of screws. Such rigid connections between the main unit and the casing are however often unable to compensate for existing tolerances, of the casing parts for example, so that visually unattractive shadow gaps result. Also in some instances vibration of the main unit is transmitted undamped by way of such rigid connections to the casing, resulting in a noise problem both for a patient in the medical examination or treatment facility and for the personnel carrying out the examination or treatment.

More complex fastening structures have to be specified during the development of the medical examination or treatment facility. Since however the planned integration of individual components of the medical examination or treatment facility can still change during the development process, the fastening structures also constantly have to be adapted structurally and/or in respect of their arrangement to said changes. Therefore a test on a newly developed fastening structure can only be meaningful after the development of the corresponding medical examination or treatment facility has been completed. This is complex and costly.

Where standard fastening means or quick-release closure systems are to be used in conjunction with said fastening structures, it is generally necessary to deploy auxiliary assembly bridges, e.g. in the form of additional sheets. Also such fastening structures are relatively expensive due to their high level of complexity and specialization.

### SUMMARY OF THE INVENTION

One object of the invention is therefore to specify a medical examination or treatment facility, which allows simple, flexible and stable fastening of assemblies and/or casing parts to a main unit of the medical examination or treatment facility.

The object is achieved by a medical examination or treatment facility as claimed in the claims. Here the medical examination or treatment facility, which is a magnetic resonance facility in particular, comprises a main unit and a support structure that can be fastened to the main unit, the support structure being a profile frame structure. Because of their particular form profile frames allow a wide range of components to be fastened without major outlay. They are simple, stable and flexible to use and allow a significant cost reduction compared with conventional steel structures. The profiles in the profile frames allow changes to be made easily to the arrangement of fastened parts at any time by moving fastening means in the profile frames.

Profiles for profile frames can be produced in many different embodiments. They can therefore be tailored easily to required loadings. Different forms and cross-sections of profiles and several applications are for example already known from the 2006 profile catalog of the company MayTec. There is also a plurality of screw systems and closure systems, also quick-release closure systems, which can be used to fasten parts to profile frames without particular measures.

The profile frame structure advantageously comprises at least one profile frame part, which can be formed to correspond to the main unit. In particular the profile frame part can be formed, perhaps curved, in the manner of a ring segment, so that it can be tailored to the form of the main unit, for example a magnet unit of a magnetic resonance device or a gantry of a computed tomography unit or radiation facility, which is generally annular in one direction, with its respective radius.

In one advantageous embodiment the profile frame part is made of aluminum or an aluminum alloy. The weight can thus be reduced compared with solutions made from steel structures. Profile frame parts made of aluminum or aluminum alloys also have vibration-damping characteristics and can thus be used advantageously to reduce the transmission of vibrations from the main unit to parts fastened to the profile frame structure.

### BRIEF DESCRIPTION OF THE DRAWINGS

Further advantages and details of the present invention will emerge from the exemplary embodiments described below and from the drawings. The examples given do not restrict the invention in any manner. In the drawings:

FIGURE shows an exemplary embodiment of an inventive medical examination or treatment facility using the example of a magnetic resonance device.

### DETAILED DESCRIPTION OF THE INVENTION

The FIGURE shows a medical examination or treatment facility 10 using the example of a magnetic resonance device. Only the parts essential to the invention are shown here. Further parts such as control systems or patient couches are not shown for purposes of clarity.

The medical examination or treatment facility 10 comprises a main unit 1, shown here in the form of a magnet unit of the magnetic resonance device. In other embodiments the main unit 1 can also be for example a gantry of a computed tomography unit or a radiation facility as the medical examination or treatment facility.

The medical examination or treatment facility also comprises a support structure 3 that can be fastened to the main unit 1, in the form of a profile frame structure 3. The profile frame structure 3 can be fastened to the main unit 1 for example by means of advantageously vibration-isolated screw connections or the like, or even by simply positioning or setting the profile frame structure 3 on the main unit 1. In the latter instance adequate frictional grip is preferably provided, for example by a corresponding intermediate layer between the profile frame structure 3 and the main unit 1, for example by means of gripping agents between the two parts 1, 3, to prevent the profile frame structure 3 slipping off the main unit 1.

In one particularly advantageous embodiment isolating elements 5 are disposed between the profile frame structure 3 and the main unit 1, to suppress the transmission of vibrations between the profile frame structure 3 and the main unit 1. To this end isolating elements 5 can be adhered to the main unit 1 and the profile frame structure 3 can be fastened to the isolating elements 5 by means of screw systems for example. The profile frame structure 3 can also advantageously be secured to the main unit 1 by securing elements 9, which prevent for example twisting or slipping (e.g. due to transportation) of the profile frame structure 3.

The profile frame structure 3 comprises at least one profile frame part 3a that can be formed to correspond to the main unit. In the exemplary embodiment shown in the FIGURE two profile frame parts 3a are curved according to the radius of the main unit 1, in order to be tailored optimally to the form of the main unit 1. The profile frame parts 3a are thus curved in the manner of ring segments. To this end the profile frame parts 3a can be formed in the manner of ring segments. After the desired forming the profile frame parts 3a retain the form given. To this end the profile frame parts 3a are advantageously made of aluminum or an aluminum alloy and are optionally embodied with a suitable cross-sectional structure. The embodiment of the profile frame parts 3a from aluminum or an aluminum alloy further has the advantage that there is a significant weight reduction compared with a steel structure, allowing easier handling for example. When forming the profile frame parts 3a it is not necessary to use special forming tools or assembly gauges, as generally have to be produced specifically beforehand for steel parts. It is thus possible to produce the profile frame parts 3a quickly, even in different forms, e.g. for test purposes during the development of the medical examination or treatment facility 10.

If the profile frame structure 3 of the medical examination or treatment facility 10 comprises two profile frame parts 3a or more, as shown in the exemplary embodiment in the FIGURE, the profile frame structure 3 advantageously also comprises struts 3b, which can be fastened between the profile frame parts 3a. The profile frame structure 3 can thus be embodied as a formation that is rigid per se and can thus also cover a desired region of the main unit 1, in that it is set on the main unit 1 in the manner of a saddle. The struts 3b here can also be made of aluminum or an aluminum alloy. However other materials, such as steel (e.g. in the form of angles) or for example pultruded plastic profiles, are also possible.

The profile frame parts 3a respectively comprise at least one groove 8 running parallel to its respective form. The profile frame structure 3 is advantageously fastened to the main unit 1 in such a manner that the at least one groove 8 does not run between the profile frame structure 3 and the main unit 1 but that the at least one groove 8 is disposed on the cross-section of the profile frame parts 3a in a direction pointing away from the main unit for example following the normal to the surface of the main unit 1 or at an angle of for example 90° or less to the normal. If in a simple embodiment a profile frame part 3a has a four-sided cross-section for example, a groove 8 is advantageously disposed on each of the four sides of the profile frame part 3a. However other cross-sectional forms and distributions of the groove or grooves are also possible depending on the area of application.

Different parts can be fastened to the at least one groove 8 in a simple manner. The fastening means to such a groove 8 here is releasable and can therefore also be eliminated quickly and with little outlay or can be moved along the groove 8 for example, to move the part to be fastened to another position. The particular advantage here is that there is a plurality of standard screw systems and quick-release closure systems precisely for aluminum profiles, it being possible to use these to attach corresponding components or the like to the profile frame structure in a simple manner.

It is possible in this manner to fix assemblies to be disposed on the outside of the main unit, such as electronic components or cable mounting panels, manometer holders, etc. and/or at least one casing part 4 of the medical examination or treatment facility 10 encasing the facility externally to the main unit 1 using the profile frame structure.

The FIGURE shows an example of a casing part 4 covering a side wall of the medical examination or treatment facility 10. Further casing parts (not shown), which can likewise be fixed to the profile frame structure and/or to already fixed other casing parts, cover the remaining side wall of the medical examination or treatment facility 10 as well as its front and rear faces.

In one advantageous embodiment casing parts 4 are fixed in particular by way of compensating elements 7 to the profile frame structure, in order to be able to compensate for any manufacturing tolerances of the casing parts 4.

1.-12. (canceled)

13. A medical device, comprising:
a main unit; and
a support structure that is a profile frame structure and is fastened to the main unit.

14. The medical device as claimed in claim 13, wherein the profile frame structure comprises a profile frame part having a form corresponding to the main unit.

15. The medical device as claimed in claim 14, wherein the form of the profile frame part is a ring segment.

16. The medical device as claimed in claim 14, wherein the profile frame part comprises a groove running parallel to the form.

17. The medical device as claimed in claim 14, wherein the profile frame part is made of an aluminum or an aluminum alloy.

18. The medical device as claimed in claim 14, wherein the profile frame part comprises a four-sided cross-section.

19. The medical device as claimed in claim 13, wherein the profile frame structure comprises at least two profile frame parts.

20. The medical device as claimed in claim 19, wherein the profile frame structure comprises a strut that is fastened between the two profile frame parts.

21. The medical device as claimed in claim 20, wherein the two profile frame parts are disposed parallel and are connected to the strut.

22. The medical device as claimed in claim 13, wherein the profile frame structure is set on the main unit of the medical device.

23. The medical device as claimed in claim 13, wherein the profile frame structure is configured to fix an assembly to be disposed on an outside of the main unit or to fix a casing part encasing the medical device externally to the main unit.

24. The medical device as claimed in claim 13, wherein the medical device is a medical examination or treatment device.

25. The medical device as claimed in claim 24, wherein the medical examination or treatment device is a magnetic resonance device.

26. The medical device as claimed in claim 25, wherein the main unit is a magnet unit of the magnetic resonance device.
